(19) United States
(12) Patent Application Publication
(10) Pub. No.: US 2012/0021136 A1
(43) Pub. Date: Jan. 26, 2012

(54) SYSTEM AND METHOD FOR CONTROLLING PLASMA DEPOSITION UNIFORMITY

(75) Inventors: Joseph P. Dzengeleski, Newton, NH (US); George M. Gammel, Marblehead, MA (US); Timothy J. Miller, Ipswich, MA (US)

(73) Assignee: VARIAN SEMICONDUCTOR EQUIPMENT ASSOCIATES, INC., Gloucester, MA (US)

(21) Appl. No.: 12/840,057

(22) Filed: Jul. 20, 2010

(51) Int. Cl. C23C 16/505; C23C 16/00; C23C 16/50

(52) U.S. Cl. 427/523; 118/723 R; 118/723 I

(57) ABSTRACT

A plasma process uniformity control apparatus comprises a plasma chamber defined by chamber walls and a plurality of magnetic elements disposed on the outside of the chamber walls. Each of the plurality of magnets is configured to supply a magnetic field directed at respective portions of the plasma inside the chamber to control the uniformity of the plasma directed toward the target substrate.

### BACKGROUND OF THE INVENTION

1. Field of the Invention

Embodiments of the invention relate to the field of plasma processing systems. More particularly, the present invention relates to a system and method for controlling uniformity of a plasma process applied to a workpiece.

2. Discussion of Related Art

Plasmas are used in a variety of ways in semiconductor processing to implant wafers or substrates with various dopants, to deposit or to etch thin films. Such processes involve the directional deposition or doping of ions on or beneath the surface of a target substrate. Other processes include plasma etching where the directionality of the etching species determines the quality of the trenches to be etched.

Generally, plasmas are generated by supplying energy to a neutral gas introduced into a chamber to form charged carriers which are implanted into the target substrate. For example, plasma deposition (PLAD) systems are typically used when shallow junctions are required in the manufacture of semiconductor devices where lower ion implant energies confine the dopant ions near the surface of the wafer. In these situations, the depth of implantation is related to the voltage applied between the wafer and an anode within a plasma processing chamber of a PLAD system or tool. In particular, a wafer is positioned on a platen, which functions as a cathode, within the chamber. An ionizable gas containing the desired dopant materials is introduced into the plasma chamber. The gas is ionized by any of several methods of plasma generation, including, but not limited to DC glow discharge, capacitively coupled RF, inductively coupled RF, etc.

Once the plasma is generated, there exists a plasma sheathe between the plasma and the surrounding surfaces, including the workpiece. The sheath is essentially a layer in the plasma which has a greater density of positive ions (i.e. excess positive charge) as compared to an opposite negative charge on the surface of the substrate. The platen and substrate are then biased with a negative voltage in order to cause the ions from the plasma to cross the plasma sheathe and be implanted into or deposited on the wafer at a depth proportional to the applied bias voltage. The depth of implantation is related to the voltage applied between the wafer and the anode. The ion dose implanted into the wafer determines the electrical activity of the implanted region and the uniformity of the dose ensures that all devices on the semiconductor wafer have operating characteristics within specified limits. Each of these parameters are critical in the semiconductor fabrication process to ensure that all devices have the desired operating characteristics.

Previously, a Faraday cup is used to measure the implant dosage amount to a wafer. However, a Faraday cup only provides information related to the total ion charge count, but does not offer any insight into uniformity. Measurement of plasma uniformity is inferred through the use of a Langmuir probe. This probe is positioned within the plasma chamber before an implant process begins or after it ends. The probe is biased to provide a current/voltage characteristic representing the current to the probe from the plasma ions and electrons as a function of the probe's bias and location. Although this measurement technique may be performed in situ, it cannot be performed during the implant, therefore it does not provide measurement information on-line during the implantation or deposition process. Plasma composition as well as process conditions may change in the time between the pre-implant measurement and the actual implant process due to various factors including wafer surface conditions, plasma ionization, etc. Unfortunately, plasma non-uniformities are likely to produce dose non-uniformity in the wafers thereby effecting device integrity as well as production yields.

Plasma uniformity has previously been modified by simultaneously biasing both the platen upon which the target wafer is disposed and a separately biasable concentric structure introduced about the electrode and sufficiently close to the target wafer to obtained the desired uniformity. Another type of uniformity modification device is disclosed in United States Patent Application, Publication No. 2003/0101935 entitled “Dose Uniformity Control for Plasma Doping Systems” assigned to the assignee of the present disclosure in which magnetic elements are mounted on a surface of the anode opposite a plasma discharge region. However, these magnets are disposed within the plasma chamber on the anode. In addition, these magnets create magnetic fields only in the region near the anode. Each of the above referenced uniformity systems and methods do not utilize an active feedback method between a measurement system and a control system to control plasma uniformity. Thus, there is a need to provide a uniformity control system and method that is used in situ during the implantation process to provide plasma uniformity control.

### SUMMARY OF THE INVENTION

Exemplary embodiments of the present invention are directed to an plasma process uniformity control device. In an exemplary embodiment, a plasma process uniformity control apparatus comprises a plasma chamber defined by chamber walls, a platen disposed within the plasma chamber for supporting a target substrate and a gas source coupled to the plasma chamber for supplying a process gas into the chamber. A power source is connected to the chamber and is configured to provide energy to ionize the process gas supplied to the chamber to form a plasma containing charged and non-charged species, said plasma directed toward a surface of said target substrate. A plurality of magnetic elements are disposed in spaced relation on the outside of the chamber walls where each of the plurality of magnets is configured to supply a magnetic field directed at respective portions of the plasma inside the chamber to control the uniformity of the plasma directed toward the target substrate.

### BRIEF DESCRIPTION OF THE DRAWINGS

FIG. 1 is a simplified schematic view of an exemplary plasma uniformity apparatus in accordance with an embodiment of the present disclosure.

FIG. 1A is a simplified top view of plasma inside a chamber 112 when exemplary magnets are turned off.

FIG. 1B is a simplified top view of the plasma inside a chamber when exemplary magnets are turned on and the effect of the generated magnetic field in accordance with an embodiment of the present disclosure.

FIG. 1C is a plot of the plasma density distributions when exemplary magnets are turned vs. when the exemplary magnets are turned on in accordance with an embodiment of the present disclosure.

FIG. 2 is a simplified schematic top view of the plasma chamber of FIG. 1 having the plurality of magnetic elements in accordance with an embodiment of the present disclosure.

FIG. 3 is an exemplary thermal wave (TW) scan of a wafer without the use of the magnetic elements of the present disclosure.

FIG. 4 is TW scan of an exemplary plasma process utilizing the magnetic elements described above with respect to FIGS. 1-2 in accordance with an embodiment of the present disclosure.

FIG. 5 is a schematic illustration of an exemplary monitoring device that may be used with plasma uniformity apparatus in accordance with an embodiment of the present disclosure.

FIG. 6 is a schematic view of the exemplary monitoring device within a plasma chamber during an exemplary plasma implantation operation.

FIG. 7 is a cross-sectional view of a gas baffle incorporating a plurality of sensors utilized in the exemplary monitoring device.

FIG. 8 is a flow chart illustrating the steps of uniformity of a plasma process in accordance with an embodiment of the present disclosure.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

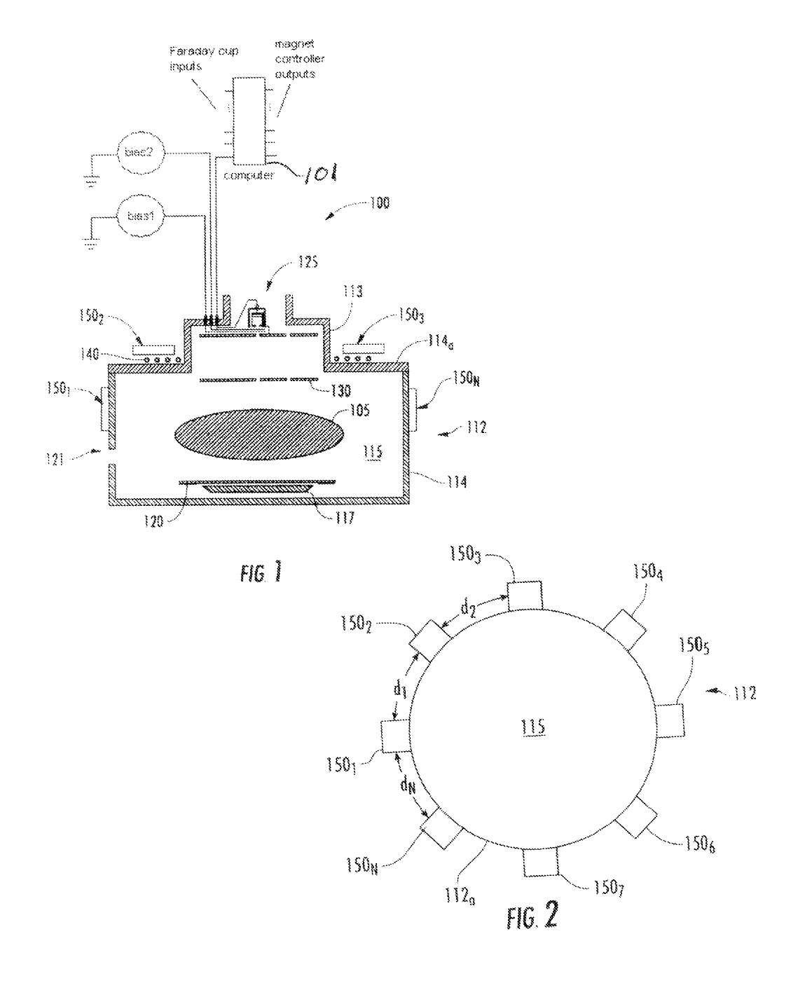

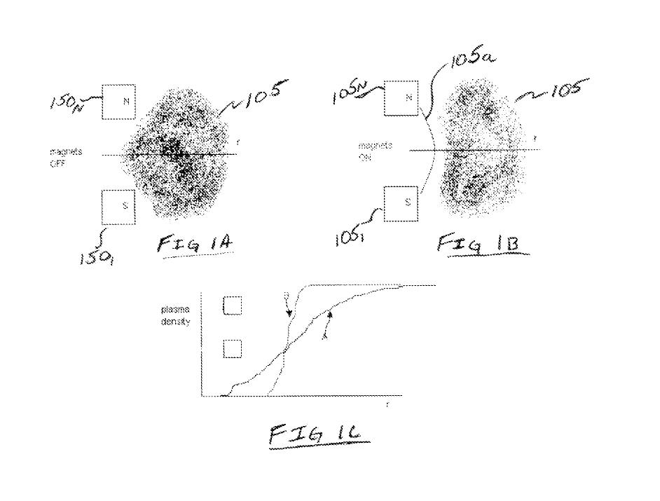

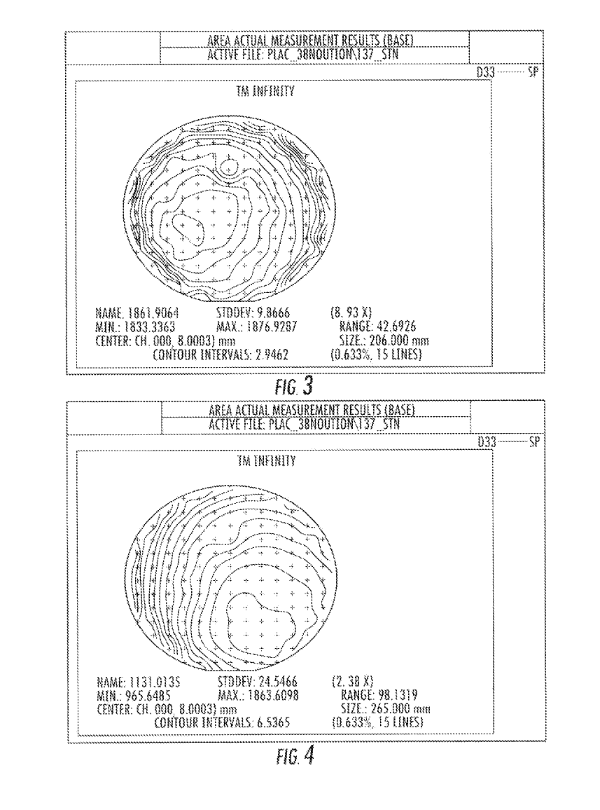

FIG. 1 is a simplified schematic view of the plasma uniformity apparatus used in a plasma deposition (PLAD) system or tool 100. A PLAD system may be, for example, a plasma etching tool, a plasma deposition tool or a plasma doping tool. The PLAD system 100 includes a plasma doping chamber 112 having an upper portion 113 and a lower portion 114 defining an enclosed interior area 115. A platen 117 is positioned within the chamber 115 in the lower portion 114. The platen 117 has an upper surface for supporting a workpiece or target substrate 120 such as, for example. a semiconductor wafer, as well as providing an electrical connection thereto. Lower portion 114 of chamber 112 may also include a loading port 121 through which a wafer or substrate is supplied for processing. Upper portion 113 of plasma chamber 115 includes an aperture 125 through which an ionizable gas containing a desired dopant for implantation into the substrate 120 is supplied. The source gas may be, for example, BF3, B2H6, PF5, etc. A baffle 130 is generally used to disperse the supplied ionizable source gas into the lower portion 114 of chamber 115 toward the target substrate 120.

RF power may be used to ionize the source gas to form plasma 105 within the chamber. In particular, a planar coil RF antenna 140 (sometimes called a planar antenna or a horizontal antenna) having a plurality of turns is positioned outside the chamber 112 and adjacent to the upper portion 113 and lower portion 114 of the chamber. In this manner, the coil and wall portion 114a of the chamber 112 form an anode. An RF power source is electrically connected to the planar coil RF antenna 140 to ensure that the impedance of the RF source is matched to the impedance of the RF antenna 140 in order to maximize the power transferred therebetween. The planar coil RF antenna 140 may be terminated with a capacitor that reduces the effective antenna coil voltage. The term “effective antenna coil voltage” is defined to mean the voltage drop across the RF antenna 140 and is the voltage experienced by the ions in the plasma chamber 112.

The RF energy ionizes the source gas supplied to chamber 112 to create plasma having the desired dopant characteristics. A negative bias voltage is applied to platen 117 and likewise to the target substrate 120 to act as a cathode. Typically, this bias voltage is a pulsed voltage potential so as to attract positive dopant ions from the plasma 105 across the plasma sheath during negative pulses of the pulsed voltage potential such that positive ions are drawn from the plasma 105 towards the wafer 120 during the pulsed periods. The ions within the plasma accelerate and implant into or deposit on the target substrate as an ion dose to form areas of impurity dopants. Generally, the ion dose is the amount of ions implanted into the target substrate or the integral over time of the ion current. The applied voltage corresponds to the implantation depth of the ions which may also be influenced by the pressure and flow rate of the gas introduced into chamber 115, duration of the RF energy, bias voltage applied to the target substrate, etc.

A plurality of magnetic elements 150₁ . . . 150_{N} is disposed in spaced relation on the outside of the walls of chamber 112 to control the uniformity of the plasma in the chamber. In particular, each of the magnetic elements 150₁ . . . 150_{N} provides a magnetic field directed at a respective portion of the plasma within the plasma chamber 112 proximate the location of the magnet to control the radial density distribution of the plasma in the chamber and consequently, the uniformity of the plasma. The strength of each of the magnetic elements may be the same or different depending on the desired magnetic field profile. The magnetic fields generated by each of the magnetic elements 150₁ . . . 150_{N} when applied to the plasma in the chamber. Magnetic elements 150₁ . . . 150_{N} may be permanent magnets such that altering poles of each respective magnet face the interior 115 of chamber 112. For example, magnet 150₁ may have a north pole directed at the interior 115, magnet 150₂ may have a south pole directed at chamber interior 115, magnet 150₃ may have a north pole directed at the chamber interior 115, etc.

In an alternative embodiment, each of the magnetic elements 150₁ . . . 150_{N} may be electromagnets where the magnetic fields of each of the magnets may be modified by controlling the flow of current through the magnet. In other words, the strength of the generated electric field from each of the magnetic elements 150₁ . . . 150_{N} is proportional to the amount of current. In this manner, by modifying the amount of current through the magnetic elements positioned around the outside of the chamber 112, the effects of the generated magnetic field on the plasma in the chamber may be controlled. For example, if that portion of the plasma in chamber 112 corresponding to magnet 150_{N} requires a greater magnetic field to change the desired density profile of the plasma, then a larger current is supplied to magnet 150_{N}. Power supplies are used to generate current through the respective magnetic elements, or each of a plurality of power supplies may be associated with a respective one of the magnetic elements to individually control the magnetic fields. A computer 101 may be configured to receive input signals from Faraday cups which measure the implant dosage and generate output signals connected to respective ones of the plurality of magnetic elements 150₁ . . . 150_{N} to control the biasing thereof based on the received input signals. A calibration may also be performed in which the field strengths of the magnetic elements are modified in a sequence and a measurement of the corresponding effect on the plasma profile is determined. Based on this calibration, computer 101 determines the setting of the magnetic elements to generate a magnetic field for the desired uniformity.

FIG. 1A is a simplified top view of plasma 105 inside chamber 112 along radius ‘r’ when exemplary magnets 150₁ and 150_{N} are turned off. This is compared to FIG. 1B which illustrates the plasma 105 when exemplary magnets are turned on generating a magnetic field 105a which modifies the density profile distribution of the plasma 105. By way of example, the magnetic elements 150₁ . . . 510_{N} may produce magnetic fields in the range of about 10-500 gauss. In addition, FIG. 1C is a plot of the plasma density distribution when exemplary magnets 150₁, 150_{N} are turned off as shown by curve A as compared to a plot of the plasma density distribution when the exemplary magnets are turned on as shown by curve B.

FIG. 2 is a simplified schematic top view of the chamber 115 having the plurality of magnetic elements 150₁ . . . 510_{N} disposed around the outside of wall 112a of chamber 112 to control the uniformity of the plasma in the chamber. Exemplary chamber 112 is illustrated as having a generally spherical shape. The magnetic elements may be spaced radial distances “d₁ . . . d_{N}” apart with an associated azimuthal spacing therebetween. For example, magnetic element 150₁ may be spaced from magnetic element 150₂ by radial distance d₁ which is parallel to the contour of wall 112a of chamber 112. Magnetic element 150₂ may be spaced from magnetic element 150₃ by radial distance d₂ which is parallel to the contour of wall 112a of chamber 112, and so on. The radial and azimuthal spacing between the respective magnetic elements are selected to provide the desired radial magnetic field profile on the plasma within the chamber. The

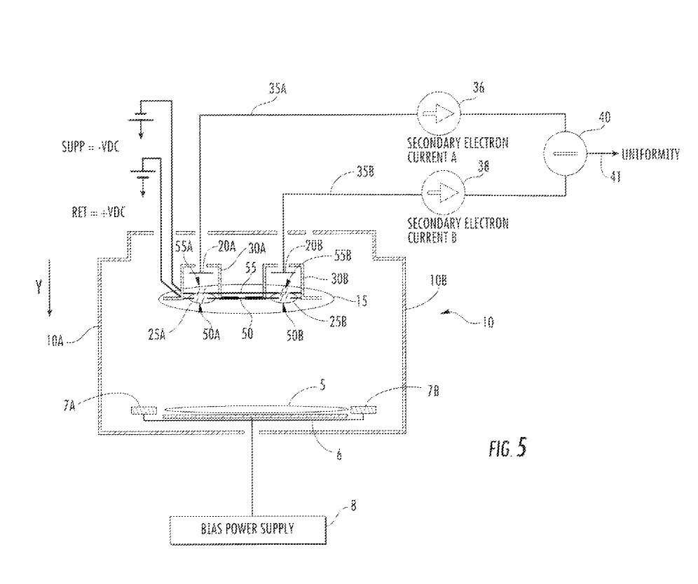

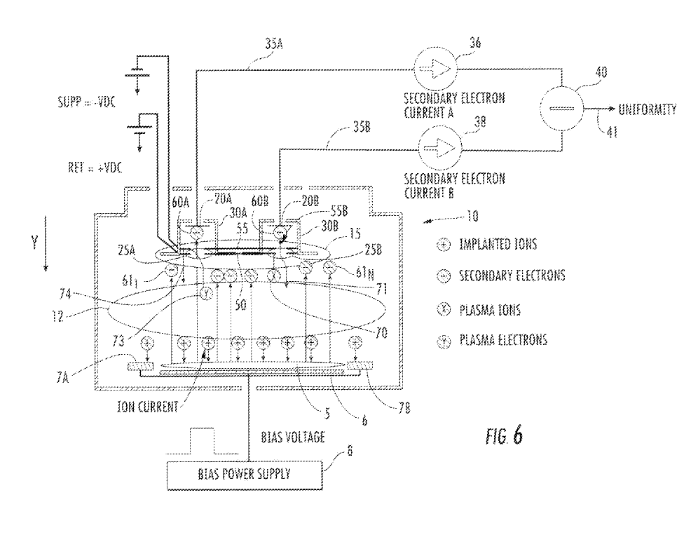

FIG. 3 is an exemplary thermal wave (TW) scan of a wafer in the direction indicated by arrow “A” without the use of the magnetic elements disposed around the outside of chamber 112 during a plasma process. This TW scan may be compared with FIG. 4 which is a scan of an exemplary plasma process utilizing the magnetic elements 150₁ . . . 150_{N} described above with respect to FIGS. 1-2. The TW scan provides a uniformity measurement on the surface of the wafer as compared to a traditional Langmuir probe which provides uniformity measurement of the plasma, but not in real time. As can be seen, the TW scan of FIG. 4 is more uniform through the use of calibration of the process by the magnetic elements 150₁ . . . 150_{N} thereby modifying the profile density of the plasma in the chamber.

The uniformity apparatus shown in FIGS. 1-2 of the present disclosure may be utilized with a real-time uniformity monitoring device to provide a uniform plasma process. In particular, based on uniformity measurements provided by the monitoring device, adjustments in the magnetic fields generated by the magnetic elements 150₁ . . . 150_{N} can be made to modify the density profile of the plasma and consequently the uniformity of the ions implanted into a target substrate 120. An example of such a plasma uniformity monitoring device may be found in co-pending application Ser. No. 12/341,574 (Attorney Docket No. 2008-123) assigned to the assignee of the present application and discussed below.

FIG. 5 is a schematic view of such a monitoring device used in a PLAD tool 100 shown in FIGS. 1-2. The monitoring device includes a plurality of sensors 20A, 20B mounted within a baffle 15 (also shown as baffle 130 in FIG. 1) in the plasma chamber. Baffle 15 may be, for example, a gas baffle positioned a distance above a workpiece 5 at one end of the plasma chamber which is configured to receive plasma processing for implantation into the workpiece 5. The workpiece may be, for example, a semiconductor wafer mounted on a platen 6 which supports the workpiece and provides an electrical connection thereto. A gas source (not shown) introduces ionizable gas into chamber 10 above the baffle 15 in direction Y at a desired pressure and flow rate. The baffle 15 disperses the gas within the chamber. Although a gas baffle 15 is disclosed, any device positioned above the workpiece 5 which is configured to disburse the gas introduced into the chamber may be employed. The gas is ionized by any of several known techniques. A bias power supply 8 provides a voltage pulse to the, platen 6, workpiece 5, and Faradays 7A and 7B which is negative with respect to an anode formed by the walls 10A and 10B and the gas baffle 15 of chamber 10. The voltage pulses accelerate the ions within the plasma which implant into workpiece 5 as an ion dose to form areas of impurity dopants within the workpiece. The voltage applied to platen 6 which is thereby applied to workpiece 5 attracts the ions across the plasma sheath for implantation. The amplitude of the voltage pulses correspond to the implantation depth of the ions into the workpiece. The dose rate and uniformity of implantation are influenced by the gas pressure, gas flow rate, gas distribution, position of the anode and the duration of the pulses, etc. The ion dose is the number of ions implanted into workpiece 5 which is equal to the integral over time of the ion current. The ion dose may be measured by a pair of Faraday cups 7A and 7B positioned contiguous with the workpiece 5 and pulsed simultaneously with the workpiece 5.

The baffle 15 includes a plurality of apertures 25A, 25B positioned radially along the surface of the baffle. Cups 30A and 30B are aligned with respective apertures 25A and 25B within which sensors 20A and 20B are housed. The cups shown in FIG. 1 are exaggerated for ease of explanation and would typically correspond with the cross sectional thickness of baffle 15. Although the present description of the sensors is disclosed as being integrally formed with baffle 15, the sensors may be housed separately and mounted to baffle 15 or positioned above workpiece 5 separately from baffle 15. Low voltage electrostatic grids 50 and 55, configured in front of the detectors 20A and 20B, are used to discriminate between relatively high energy, implant generated, secondary electrons and low energy plasma ions and electrons. In particular, a first grid 50 is disposed between sensors 20A, 20B and workpiece 5 and extends across apertures 25A and 25B. Grid 50 includes a plurality of screen portions 50A and 50B aligned with apertures 25A and 25B respectively to allow secondary electrons to pass through the apertures to sensors 20A and 20B. Because apertures 25A and 25B are not biased, they do not suffer from unwanted deposition or erosion from the secondary electrons or the low energy plasma ions and electrons passing through the apertures. Grid 50 is biased with a positive DC voltage (+VDC) and is configured to prevent low energy ions from the plasma within chamber 10 from leaking to sensors 20A and/or 20B during implantation. A second grid 55 is disposed between sensors 20A, 20B and first grid 50 and extends across apertures 25A and 25B. Grid 55 includes a corresponding plurality of screen portions 55A and 55B aligned with apertures 25A and 25B respectively to allow implant generated secondary electrons to pass through the apertures to sensors 20A and 20B. Grid 55 is biased with a negative DC voltage (−VDC). This negative voltage is substantially below the energy of the implant generated secondary electrons. Thus, when secondary electrons pass through apertures 25A and 25B within a corresponding cup 30A and/or 30B, they are counted by one of the respective sensors 20A or 20B. In addition, relatively low energy secondary electrons are generated at the surface of the sensor 20 a or 20 B by the implant generated secondary electrons' impact with the sensor 20A or 20B, the negative voltage on the inner grid 55 is set high enough to repulse these particles back toward the sensor so they may be collected and counted by the sensor, keeping the measurement true. Grid 55 serves another purpose in that it disallows relatively low energy plasma electrons from entering the cup 30A or 30B by repulsing them back toward the plasma 12.

As will be described in more detail below, sensor 20A detects the number of relatively high energy, implant generated, secondary electrons which pass through aperture 25A and generates a current signal 36 proportional to the number of secondary electrons detected. These secondary electrons are generated above the region of workpiece 5 aligned with aperture 25A. The current signal 36 is supplied to current comparator circuit 40 via connection 35A. Similarly, sensor 20B detects the number of secondary electrons which pass through aperture 25B and generates a current signal 38 proportional to the number of secondary electrons detected. These secondary electrons are generated above the region of workpiece 5 aligned with aperture 25B. The current signal 38 is supplied to current comparator circuit 40 via connection 35B. Current comparator circuit 40 compares the current signals 36 and 38 and outputs a differential current signal 41. If the current signals 35A and 35B are equal, the differential current signal 41 will be zero indicating that the plasma process is equal at the two regions on the workpiece aligned with apertures 25A and 25B. If the current signals 35A and 35B are different, then the differential current signal 41 will not be zero indicating that the plasma process is not equal in these two regions of the workpiece 5. As can be inferred from the above description, the more sensors used to detect secondary electrons emitted from the surface of workpiece 5 the more information one obtains regarding process uniformity across the workpiece. In addition, if a particular plasma recipe requires a desired non-uniformity characteristic across workpiece 5 or a recurring non-uniform characteristic, then current comparator circuit provides the compared current calculation associated with each of the sensors 20A, 20B.

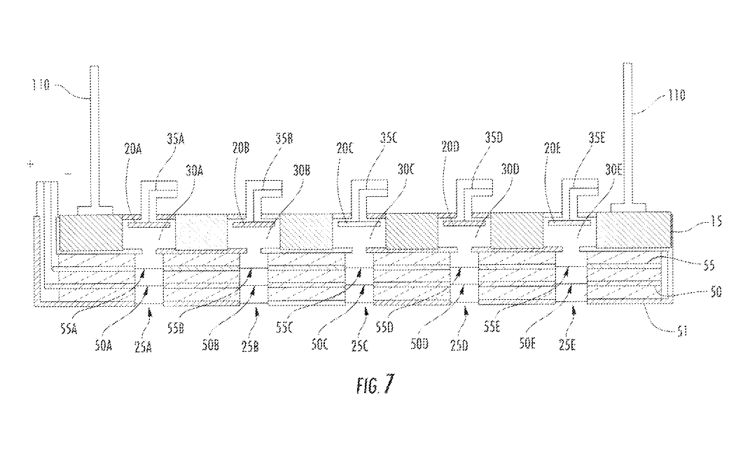

FIG. 6 is a schematic view of the monitoring device having a plurality of sensors 20A, 20B during a plasma implantation operation. In particular, an ionizable gas is introduced into chamber 10 above baffle 15 in direction Y at a desired pressure and flow rate. Plasma 12 is then created in the plasma chamber 10 by addition of energy by any of the known methods. Bias power supply 8 provides a negative voltage bias to workpiece 5 with respect to the anode formed by the walls of chamber 10 and the gas baffle 15. This causes positive ions (depicted with a “+” sign in FIG. 6) to be accelerated through plasma sheath 12 and implanted into workpiece 5 to form a uniform distribution of impurity dopants within workpiece 5. When the ions are implanted into workpiece 5, secondary electrons (depicted with a “−” sign in FIG. 6) are emitted from the surface of workpiece 5 which are then accelerated orthogonally toward baffle 15. The energy of the secondary electrons is determined by the implant bias voltage as the electrons are accelerated through the plasma sheath 12 above workpiece 5. This energy is substantially equal to the energy of the implanted ions. These secondary electrons are detected by the sensors and a proportional current signal is generated and compared with the currents generated by the other sensors positioned above the surface of the workpiece. For example, secondary electrons 60A and 60B are emitted from the surface of workpiece 5 orthogonally aligned with cavities 30A and 30B via apertures 25A and 25B respectively. Secondary electrons 60A and 60B pass through screen portions 50A and 50B of first grid 50 and screen portions 55A and 55B of second grid 55 and are received by sensors 20A and 20B. In response to the detection of secondary electrons 60A, sensor 20A generates current 36 and supplies it to comparator circuit 40 via line 36. Similarly, in response to the detection of secondary electrons 60B, sensor 20B generates current 38 and supplies it to comparator circuit 40 via line 35B. Current comparator circuit 40 compares the current signals 36 and 38 and outputs a differential current signal 41. Because a differential current signal is being evaluated based on the detected secondary electrons, it is not critical to determine the absolute number of secondary electrons produced by ions impacting the surface of the workpiece. Rather, the differential current signal indicates that the number of electrons detected at the respective locations of the sensors 20A, 20B is equivalent or not equivalent. As noted briefly above, a particular recipe may require a non-uniform implantation or non-uniform characteristic associated with particular locations across the wafer. In this case, current comparator circuit would provide a particular current signal in response to this non-uniformity.

Secondary electrons 61₁-61_{N} which are emitted orthogonally from the surface of workpiece 5 as indicated by arrows 62₁-62_{N} are not aligned with either cavity 30A or 30B and thus, are not detected by sensors 20A and 20B. Again, the depiction of sensors 20A and 20B in FIG. 5 is for ease of explanation and the monitoring device utilized in chamber 10 has a sufficient number of sensors to accurately provide a uniformity measurement. Low energy plasma ions 70 (depicted with an “x” in FIG. 6) which is aligned with aperture 25A or 25B is prevented from entering the sensor 20A or 20B by grid 50 which is biased with a positive voltage that exceeds the energy of the plasma ion. Low energy plasma ion 70 is repelled back toward the plasma 12 as indicated by arrow 71. Plasma electron may also pass through aperture 25A or 25B. This representative plasma electron passes through aperture 25A and gains energy form the positive bias on grid 50, but because grid 55 is biased with a negative DC voltage (−VDS) which exceeds the bias on grid 50, plasma electron 73 is repelled back toward grid 50 and the plasma 12 as indicated by arrow 74. In this manner, the monitoring device detects the secondary electrons emitted from the surface of workpiece 5 in situ and during ion implantation to monitor the uniformity of the plasma process taking place.

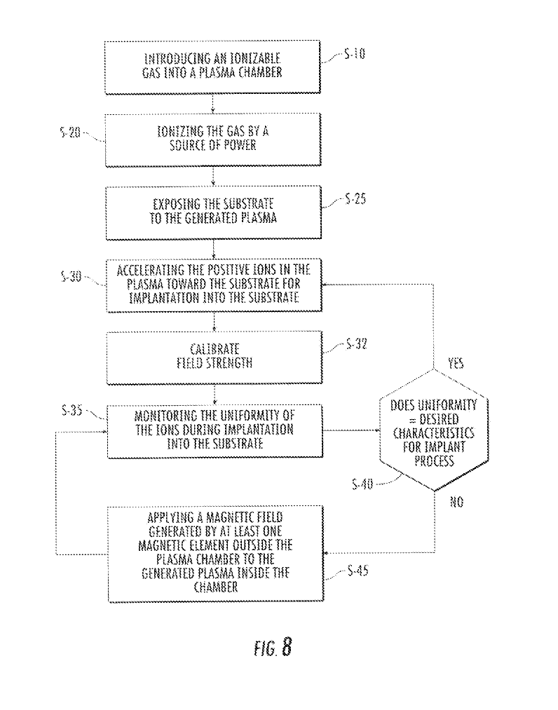

FIG. 7 is a schematic cross-section of an alternative embodiment of baffle 15 incorporating multiple sensors 20A-20E radially across the baffle. As noted above, baffle 15 is positioned above a workpiece within a plasma chamber by support members 110. Alternatively, this type of structure could be an integral part of the plasma chamber. Baffle 15 includes a plurality of cavities 30A-30E where each cavity houses a respective sensor 20A-20E. Although the cavities 30A-30E are illustrated as equally spaced radially across baffle 15, the positioning and location of the cavities is at the discretion of the user. Each of the sensors 20A-20E is connected to a comparator circuit (similar to comparator circuit 40 illustrated in FIGS. 5 and 6) via respective lines 35A-35E. A ground plane 51 is disposed between grid 50 and workpiece 5. Ground plane 51 acts as a shield for plasma contained within chamber 10. In particular, the interior of chamber 10 is at an equipotential such that the plasma within the chamber is surrounded by ground potential. A plurality of apertures 25A-25E located across ground plane 51 is aligned with each of the sensors 20A-20E. Grid 50 extends across each of the cavities 30A-30E and includes corresponding screen portions 50A-50E aligned with apertures 25A-25E and sensors 20A-20E respectively. Again, grid is biased with a positive DC voltage (+VDC) to prevent low energy plasma ions from reaching sensors 20A-20E. Similarly, grid 55 extends across each of the cavities 30A-30D and includes corresponding screen portions 55A-55E aligned with apertures 25A-25E and sensors 20A-20E respectively. Grid 55 is biased with a negative DC voltage (−VDC) used to trap the secondary electrons in cavities 30A-30E and detected by sensors 20A-20E as well as repelling plasma electrons back toward the plasma. In this manner, a plurality of sensors 20A-20E are integrally formed within baffle 15 to detect secondary electrons emitted from a workpiece and accelerated orthogonally within a plasma chamber. By using sufficiently sized apertures the secondary electrons are detected or sampled from a relatively large area of workpiece 5 and therefore, is not subject to local differences in secondary emissions or photoresist coverage present on the workpiece.

In addition to monitoring uniformity during implant, by controlling the biasing voltages to grids 50 and 55, the plasma within the chamber 10 may be characterized before an implant begins. For example, the positive bias can be held at a constant voltage on grid 50 while the negative bias on grid 55 is swept over a range of voltages The output from each of the sensors, monitored during the voltage sweep, will describe the energy distribution of electrons in the plasma. Similarly, the positive voltage can be swept, describing the energy distribution of the plasma ions. Those skilled in the art can extract more information about the plasma by manipulation of these voltages. In an alternative configuration, the sensors 20A-20E themselves can be biased either positively or negatively, with or without the grids being biased, to extract plasma characteristics.

FIG. 8 is a flow diagram illustrating the steps associated with modifying the uniformity of a plasma implantation process. A workpiece 120 is mounted on a platen or support within a plasma chamber 100. An ionizable gas is introduced into the plasma chamber at step S-10 and the gas is ionized by a power source at step S-20. The substrate is exposed to a plasma containing positive ions from the ionizable gas at step S-25. The positive ions are accelerated to an implant energy toward the platen for implantation into the substrate at step S-30. The field strength of the magnetic field generated by the magnetic elements is calibrated at step S-32. At step S-35, the uniformity of the ions during implantation into the substrate is monitored. This monitoring may be performed by the monitoring device described above with reference to FIGS. 5-7. Alternative uniformity monitors may also be used to provide real-time in situ monitoring of the implant process. A determination is made at step S-40 if the implant process conforms to the uniformity characteristic for the particular implant process. If the uniformity does conform then the process continues to implant the ions at step S-50 until the desired implantation is complete. If the uniformity does not conform to the desired characteristics, then the process continues to step S-45 where the magnetic fields generated by one or more of a plurality of magnetic elements is applied to the plasma generated inside the plasma chamber. The process returns to the step (S-35) of monitoring the uniformity of the plasma during process implantation. This process continues until the ions having the desired uniformity characteristics are implanted into the substrate

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A process uniformity control apparatus comprising:
a plasma chamber defined by chamber walls;
a platen disposed within said plasma chamber for supporting a target substrate;
a gas source coupled to said plasma chamber for supplying an process gas to said chamber,
a power source connected to said chamber and configured to provide energy to ionize said process gas supplied to said chamber to form a plasma containing charged and non-charged species directed toward a surface of said target substrate; and
a plurality of magnetic elements disposed in spaced relation on the outside of the chamber walls, each of said plurality of magnets configured to supply a magnetic field directed at respective portions of said plasma within said chamber to control the uniformity of said plasma directed toward said target substrate.

2. The process uniformity control apparatus of claim 1 further comprising an anode spaced from said platen in said plasma chamber, said plasma being generated between said anode and said platen.

3. The process uniformity control apparatus of claim 2 further comprising a plurality of coils disposed around at least a portion of the chamber walls, said coils and said corresponding chamber walls defining said anode.

4. The process uniformity control apparatus of claim 3 wherein said plurality of coils receive RF energy to ionize said process gas.

5. The process uniformity control apparatus of claim 1 wherein said platen is biased with a negative voltage to attract said charged and non-charged species toward said target substrate.

6. The process uniformity control apparatus of claim 1 wherein said process gas contains desired dopant species for implantation into said target substrate.

7. The process uniformity control apparatus of claim 1 wherein said power source is a first power source, said process uniformity control apparatus further comprising a second power source connected to at least one of said plurality of magnets, said second power source configured to change a magnetic field associated with said at least one of said plurality of magnets.

8. The process uniformity control apparatus of claim 1 wherein a first and second of said purality of magnetic elements is separated by a first radial distance.

9. The process uniformity control apparatus of claim 8 wherein a third and a fourth of said purality of magnetic elements is separated by a second radial distance

10. The process uniformity control apparatus of claim 9 wherein said first and second radial distances are equal.

11. The process uniformity control apparatus of claim 9 wherein said first and second radial distances are unequal.

12. The process uniformity control apparatus of claim 1 wherein each of said magnets being connected to a power source to control respective magnetic fields applied to the plasma in the chamber, said magnetic fields configured to control the density distribution of the plasma in the plasma chamber based on a plurality of current signals representative of the measurement of the dose uniformity of the ions implanted into the workpiece.

13. A method of controlling plasma process uniformity comprising:
introducing an ionizable gas into a plasma chamber, said gas containing a desired dopant;
ionizing the gas using a source of power;
exposing a substrate to a plasma containing positive ions of said ionized gas; accelerating said positive ions to an implant energy toward said substrate;
monitoring a uniformity of the ions during implantation into the substrate; and
applying a magnetic field from at least one magnetic element located outside the plasma chamber to the generated plasma inside the chamber.

14. The method of claim 13 wherein, after monitoring the uniformity of the ions during implantation into the substrate, the method further comprising determining if the uniformity matches desired characteristics for a particular implant process.

15. The method of claim 14 wherein the applied magnetic field is modified by changing a current applied to the at least one magnetic element.

16. The method of claim 13 wherein the positive ions are accelerated to an implant energy toward said substrate by biasing the workpiece.
